(19) United States
(12) Patent Application Publication
(10) Pub. No.: US 2016/0222804 A1
(43) Pub. Date: Aug. 4, 2016

(54) A COMPONENT FOR A TURBOMACHINE AND A METHOD FOR CONSTRUCTION OF THE COMPONENT

(71) Applicant: SIEMENS AKTIENGESELLSCHAFT, München (DE)

(72) Inventors: Fathi AHMAD, Kaarst (DE); Eckart SCHUMANN, Berlin (DE); Werner STAMM, Mülheim an der Ruhr (DE)

(73) Assignee: SIEMENS AKTIENGESELLSCHAFT, München (DE)

(21) Appl. No.: 15/026,683

(22) PCT Filed: Sep. 3, 2014
(86) PCT No.: PCT/EP2014/068698

§ 371 Date: Apr. 1, 2016

(30) Foreign Application Priority Data
Oct. 2, 2013 (EP) 13187122.0

(51) Int. Cl. F01D 5/28; F01D 9/04; C23C 16/44; C23C 28/02; C23C 14/22; C23C 4/134; F01D 5/14; F01D 25/08

(52) U.S. Cl. CPC F01D 5/288; F01D 5/147; F01D 9/041; F01D 25/08; C23C 28/022; C23C 14/221; C23C 4/134; C23C 16/44; F05D 2220/31; F05D 2220/32; F05D 2230/90; F05D 2230/312; F05D 2230/313; F05D 2300/5023; F05D 2300/132; F05D 2300/16; F05D 2300/177

(57) ABSTRACT

A component (1) for a turbomachine and a method for construction thereof: The component includes an inner core (6) and a first thermal bond coating (11) on the inner core (6), and a second thermal bond coating (12) on the first thermal bond coating (11). The first thermal bond coating (11) is sandwiched between the inner core (6) and the second thermal bond coating (12). A second operating temperature (T₂ₘₐₓ) of the second thermal bond coating (12) is higher than a first operating temperature (T₁ₘₐₓ) of the first thermal bond coating (11).

### CROSS-REFERENCE TO RELATED APPLICATIONS

The present application is a 35 U.S.C. §§371 national phase conversion of PCT/EP2014/068698, filed Sep. 3, 2014, which claims priority of European Application No. 13187122.0, filed Oct. 2, 2013, the contents of which are incorporated by reference herein. The PCT International Application was published in the English language.

### TECHNICAL FIELD

The present invention relates to the field of turbomachines, such as gas turbines and steam turbines, and particularly to a component for a turbomachine, such as airfoils, and a method for construction of the component.

### TECHNICAL BACKGROUND

A turbomachine, for example a gas turbine or a steam turbine, is widely used in the field of power generation. During power generation, the fuel in the turbomachine undergoes combustion, during which the chemical energy contained in the fuel is converted into mechanical energy, which is thereafter converted into electrical energy. The combustion of the fuel inside the turbomachine is a highly exothermic reaction, whereby tremendous amount of heat (greater than 1173K) is generated. Thus, the turbomachine and its various components are required to operate at high temperatures to achieve high efficiency.

Certain components of the turbomachine are exposed to operating temperatures of the order of 1173K or more. As the operating temperatures increase, the aforementioned components of the turbomachine face higher thermal loading, either in the form of static temperature or in the form of temperature gradients. In order to overcome the harsh effects of high thermal loading, the temperature durability of the turbomachine components must correspondingly increase. For example, components such as blades and/or vanes of the turbomachine face higher thermal loading as compared to other parts of the turbomachine.

Currently, a thermal bond coating is used to provide insulation of these turbomachine components from the very high operating temperatures and the thermal loadings caused thereby. Typically, the aforementioned thermal bond coating comprises a metallic bond coating, a thermally grown oxide, and a ceramic topcoat. Components such as turbine blades and turbine vanes need the metallic coating as a bond coating or as an overlay coating. The metallic bond coating has a certain lifetime depending on its thickness and on the temperature and the time duration to which the coating is exposed during the operation of the turbomachine.

However, metallic bond coatings of different qualities and with different properties are available. Components of the turbomachine that are coated with a low quality bond coating should not be operated in high thermal loading conditions, because the low quality bond coating cannot withstand such high thermal loads, and the low quality bond coating would chip off or crack. Therefore, the low quality metallic bond coating would not be able to provide the necessary protection to components that are exposed to high operating temperature. However, the low quality bond coating would still be sufficient to protect components which are exposed to lower temperatures, for example operating temperatures less than 900° C. In order to overcome the aforementioned impediment, a high quality bond coating is used under the aforementioned high temperature conditions. However, a high quality bond coating is more expensive than the low quality bond coating. Therefore, the manufacturing cost of the components coated with the high quality bond coating and the turbomachine thereof increase tremendously.

Therefore, there is not only a need to optimize the manufacturing cost, but also to achieve a balance between performance and manufacturing cost for bond coatings, whereby the same can be applied to turbomachine components that are required to endure high thermal loads during operation of the turbomachine.

### SUMMARY OF THE INVENTION

It is an object of the present invention to provide a solution for bond coating turbomachine components that renders optimum performance, and also protects the turbomachine components adequately without the need to increase the manufacturing cost of the bond coated turbomachine components.

The aforementioned object is achieved by a component for a turbomachine, and a method for construction of the component according to the disclosure herein.

The underlying object of the present invention is to reduce the manufacturing cost and optimize the performance of components for a turbomachine, especially if the components are exposed to very high operating temperatures, for example more than 1173K. A component comprising a bi-layered thermal bond coating approach comprising two different thermal bond coatings is disclosed herein for the achievement of the aforementioned object. The bilayered thermal bond coating combines the advantages of the individual thermal bond coatings to render enhanced durability and superior performance of the component.

The aforementioned component for the turbomachine comprises an inner core with an outer surface. A first thermal bond coating is arranged at least on a portion of the inner core. Thereafter a second thermal bond coating is arranged on the first thermal bond coating. The first and the second thermal bond coatings are arranged such that the first thermal bond coating is sandwiched between the inner core and the second thermal bond coating. The maximum operating temperature T₂ₘₐₓ of the second thermal bond coating is greater than the maximum operating temperature T₁ₘₐₓ of the first thermal bond coating. The chemical compositions of the first and the second thermal bond coatings are different in order to render different maximum operating temperatures.

The maximum operating temperature refers to a temperature for which the coating is still intact on the inner core, i.e. the coating is not destroyed or cracked or broken until the maximum operating temperature is attained.

Nevertheless, the first thermal bond coating can be arranged on the entire extent of the inner core, and thereafter the second thermal bond coating can be arranged on the first thermal bond coating. Therewith, the entire component is thermally bond coated in a bi-layered manner. Furthermore, the component can be an airfoil, a platform segment whereon the airfoil is mounted, et cetera.

In accordance with an embodiment of the present invention, a thickness (t₁) of the first thermal bond coating is greater than a thickness (t₂) of the second thermal bond coating.

It is beneficial for reducing the manufacturing cost of the component if the first thermal bond coating comprises an inexpensive low quality bond coat material and the second thermal bond coating comprises an expensive high quality bond coat material.

In accordance with further embodiments of the present invention, the thickness (t₂) of the second thermal bond coating lies in the range of 10 μm to 100 μm, and the thickness (t₁) of the first thermal bond coating lies in the range of 100 μm to 300 μm. The aforementioned thicknesses (t₁ and ₜ₂) of the first and the second thermal bond coatings are beneficial to achieve optimal thermal performance and optimal cost reduction of the component.

In accordance with another embodiment of the present invention, the first thermal bond coating is capable of adsorbing Sulphur. The inner core can be protected from Sulphur attacks, because the Sulphur is adsorbed by the first thermal bond coating. Thus, the operational life of the component is enhanced.

In accordance with yet another embodiment of the present invention, a Sulphur adsorption coefficient of the first thermal bond coating is greater than a Sulphur adsorption coefficient of the second thermal bond coating. This feature is beneficial in offering enhanced protection of the inner core even in the event of depletion of the second thermal bond coating due to Sulphur attacks on the second thermal bond coating.

In accordance with yet another embodiment of the present invention, a percentage by weight of Chromium present in the first thermal bond coating is greater than a percentage of Chromium by weight present in the second thermal bond coating. The capability of Chromium to adsorb Sulphur is exploited. A higher presence of Chromium in the first thermal bond coating as compared to the second thermal bond coating is beneficial in rendering enhanced protection to the inner core in the event of depletion of the second thermal bond coating.

In accordance with yet another embodiment of the present invention, the second thermal bond coating comprises Rhenium. Rhenium enhances the durability and the wear resistance of the component. Additionally, the component can be exposed to higher operating temperatures due to the presence of Rhenium. Furthermore, the oxidation of the component is reduced due to the presence of Rhenium. The operational life of the component and the thermal performance of the component are thereby enhanced.

In accordance with further embodiments of the present invention, the first maximum temperature T₁ₘₐₓ is less than or equal to 1173K, and the second maximum temperature T₂ₘₐₓ is greater than 1173K.

In accordance with yet another embodiment of the present invention, an outer ceramic coating is included in the component. The outer ceramic coating is arranged on the second thermal bond coating. The arrangement of the outer ceramic coating is such that the second thermal bond coating is sandwiched between the portion of the inner core and the outer ceramic coating. The inner core, the first thermal bond coating, and the second thermal bond coating are protected by the presence of the outer ceramic core.

In accordance with a method for construction of the component according to any of the aforementioned embodiments, the first thermal bond coating is provided on the inner core, and the second thermal bond coating is provided on the first thermal bond coating.

In accordance with further embodiments of the present invention, the first thermal bond coating is provided on the inner core by overlaying the first thermal bond coating on the inner core. The second thermal bond coating is provided on the first thermal bond coating by overlaying the second thermal bond coating on the first thermal bond coating.

In accordance with another embodiment of the present invention, the overlaying of the bond coating can be provided by any of the processes, viz. Electron Beam Physical Vapor Deposition, Air Plasma Spray, High Velocity Oxygen Fuel, Electrostatic Spray Assisted Vapor Deposition, and Direct Vapor Deposition.

The aforementioned and other embodiments of the present invention related to a component for a turbomachine and a method for construction of the component will now be addressed with reference to the accompanying drawings of the present invention. The illustrated embodiments are intended to illustrate, but not to limit the invention. The accompanying drawings herewith contain the following figures, in which like numbers refer to like parts, throughout the description and drawings.

### BRIEF DESCRIPTION OF THE DRAWINGS

The figures illustrate in a schematic manner further examples of the embodiments of the invention, in which:

FIG. 1 depicts a perspective view of an exemplary component for the turbomachine,

FIG. 2 depicts a cross-sectional view of the component referred to in FIG. 1 along a section II-II,

FIG. 3 depicts a portion III of the component referred to in FIG. 2 in accordance with one or more embodiments of the present invention, and

FIG. 4 depicts a flowchart of a method for construction of the component referred to in FIG. 1.

### DESCRIPTION OF PREFERRED EMBODIMENTS

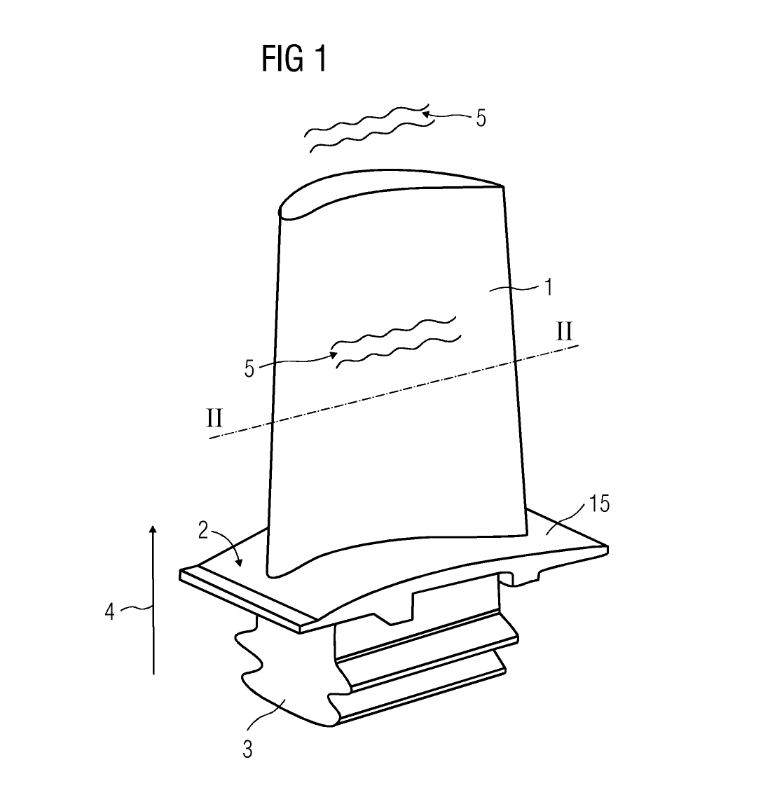

A perspective view of an exemplary component 1 for a turbomachine (not shown), in accordance with one or more embodiments of the present invention, is depicted in FIG. 1.

For the purpose of elucidation of the present invention, the component 1 of FIG. 1 is considered to be an exemplary airfoil for the turbomachine. The airfoil 1 may either be a rotatable blade comprised in a rotor section (not shown) of the turbomachine or the airfoil 1 can be a stationary vane comprised in a stator section (not shown) of the turbomachine.

The airfoil 1 according to FIG. 1 is arranged on a platform segment 2 and the platform segment 2 is furthermore attached to a root segment 3. The airfoil 1 extends in a radially outward direction 4 from the platform section 2, and the radially outward direction 4 is indicated by reference arrow ‘4’. Herein, the radial direction 4 is perpendicular to an axis of rotation of the rotor of the turbomachine. The platform segment 2 and the root segment 3 facilitate contiguous arrangement of a plurality of such airfoils 1, for facilitating the construction of either the stator section and/or the rotor section for the turbomachine.

The aforementioned turbomachine can be construed to be a gas turbine, a steam turbine, a turbofan, etc. The turbomachine may be used in the field of power generation, wherein the chemical energy and/or the mechanical energy of a working fluid is converted into mechanical and/or electrical energy.

The airfoil 1 is subjected to extremely high temperatures (for example, greater than 12730K) during the operation of the aforementioned turbomachine. Furthermore, the airfoil 1 can be subjected to extremely high temperature gradients, i.e. varying temperatures. Thus, extremely high thermal fatigues are experienced by the airfoil 1 during its operation. In addition to the aforementioned thermal fatigues, the airfoil 1 experiences mechanical fatigue either by virtue of movement of the airfoil 1 and/or the movement of hot gases 5 over the airfoil 1. Furthermore, the airfoil 1 is subjected to contact with various chemicals and contaminants present in the fuel and/or the working fluid, which can cause mechanical abrasions, corrosions, etc., thereby causing surface damage, wear and tear of the airfoil 1, et cetera. Therewith, a reduction in the operational life of the airfoil 1 is experienced. The manner in which the operational life of the airfoil 1 can be enhanced in accordance with the teachings of the present invention is explained below.

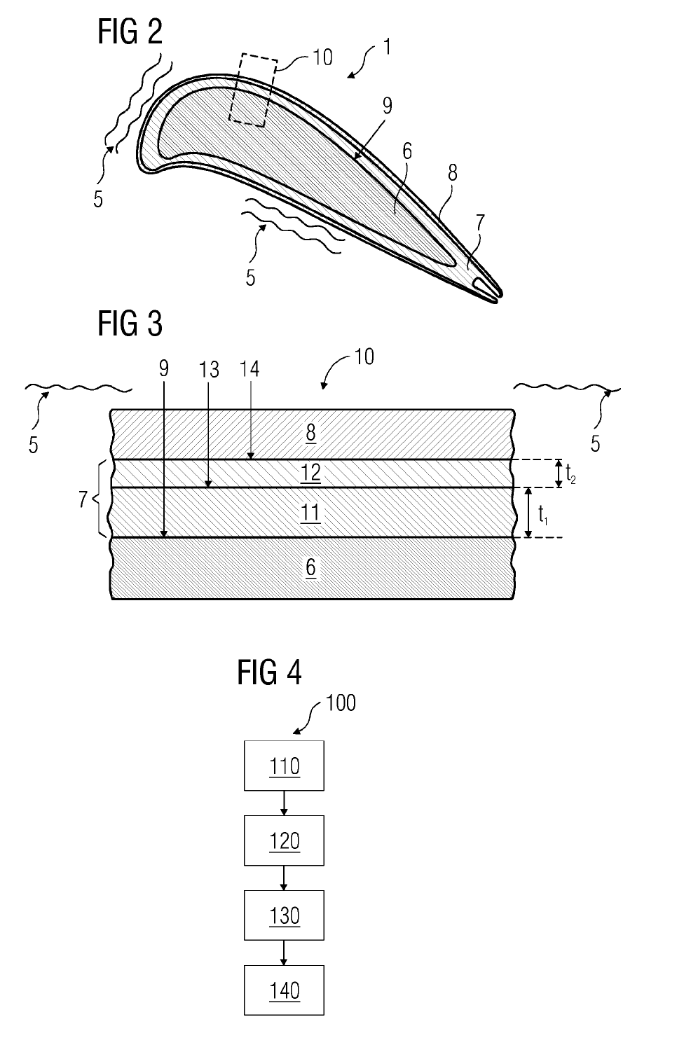

A cross-sectional view of the airfoil 1 as viewed along a section II-II is depicted in FIG. 2.

The airfoil 1 comprises an inner core 6, a thermal bond coating layer 7, and an outer ceramic coating 8. The inner core 6 may either be a solid core or a hollow core, and the inner core 6 may be constructed from a metal, an alloy, a composite material, etc. The inner core 6 comprises an outer surface 9 whereon the thermal bond coating layer 7 is arranged. Thereafter, the outer ceramic coating 8 is arranged on the thermal bond coating layer 7. The thermal bond coating layer 7 is sandwiched between the inner core 6 and the outer ceramic coating 8.

Arrangement of the thermal bond coating layer 7 on the inner core 6 can be achieved by overlaying the thermal bond coating layer 7 on the inner core 6. The overlaying of the thermal bond coating layer 7 on the inner core 6 can be achieved by using any of the well-known processes such as Electron Beam Physical Vapor Deposition, Air Plasma Spray, High Velocity Oxygen Fuel, Electrostatic Spray Assisted Vapor Deposition, Direct Vapor Deposition, etc. The aforementioned techniques for overlaying the thermal bond coating layer 7 on the inner core 6 are well-known in the art, and are not explained herein for the purpose of brevity.

In the airfoil 1 in FIG. 2, the entire inner core 6 is overlaid with the thermal bond coating layer 7. However, without loss of generality, it is also possible to overlay the thermal bond coating layer 7 only on a selected region of the inner core 6. Thereafter, the outer ceramic coating 8 is overlaid on the thermal bond coating layer 7, which is overlaid on the selected region of the inner core 6. That region may be selected based on an analysis of the thermal stresses, the mechanical stresses and the spallation that can be possibly experienced during the operation of the airfoil 1. For example, the aforementioned region can be a hotspot, which is prone to experience very high thermal stresses, mechanical stresses and spallation.

A magnified portion 10 of the airfoil 1 comprising the inner core 6, the thermal bond coating layer 7, and the outer ceramic coating 8 is depicted in FIG. 3.

Refer to preceding Figures for explanation of FIG. 3. In accordance with the present invention, the thermal bond coating layer 7 comprises a first thermal bond coating 11 and a second thermal bond coating 12. The first thermal bond coating 11 and the second thermal bond coating 12 are different. For example, the thermal bond coatings 11,12 can be metallic bond coatings. However, the first thermal bond coating 11 and the second thermal bond coating 12 together form the thermal bond coating layer 7.

The first thermal bond coating 11 is preferably arranged on the outer surface 9 of the inner core 6, which may be achieved for example by overlaying the first thermal bond coating 11 on the outer surface 9 of the inner core 6 by means of any of the aforementioned processes. Similarly, the second thermal bond coating 12 is preferably arranged on the first thermal bond coating 11, which may again be achieved for example by overlaying the second thermal bond coating 12 on an outer surface 13 of the first thermal bond coating 11 again by means of any of the aforementioned processes.

Thereafter, the outer ceramic coating 8 is overlaid on an outer surface 14 of the second thermal bond coating 12. It may be noted herein that the second thermal bond coating 12 is sandwiched between the inner core 6 and the outer ceramic coating 8.

The second thermal bond coating 12 is comprised of a superior quality material, as compared to the material of which the first thermal bond coating 11 is comprised. Correspondingly, the material of the second thermal bond coating 12 is more expensive than the material of the first thermal bond coating 11. For example, the second thermal bond coating 12 may comprise by weight percentage: Cobalt—24 to 26%, Chromium—16 to 18%, Aluminium—9.5 to 11%, Yttrium—0.2 to 0.4%, Rhenium—1.2 to 1.8%, and the remaining comprises Nickel. The first bond coating may comprise: Nickel—29 to 31%, Chromium—27 to 29%, Aluminium—7 to 8%, Yttrium—0.5 to 0.7%, Silicon—0.3 to 0.7% Si, and the remainder comprises Cobalt.

The first thermal bond coating 11 is capable of adsorbing Sulphur, because the first thermal bond coating 11 is comprised of Chromium. During the operation of the turbomachine, the airfoil 1 is exposed to sulphur dioxide, which is produced as a result of the combustion of fuel in the turbomachine. The exposure of the airfoil 1 to Sulphur can lead to damage to material of the airfioil, which can hamper the operation of the airfoil. In such a situation, the inner core 6 of the airfoil can be protected from Sulphur attacks, because the first thermal bond coating 11 is arranged on the outer surface 9 of the inner core 6, and the first thermal bond coating 11 is capable of adsorbing Sulphur.

The percentage content by weight of Chromium in the first thermal bond coating 11 is preferably greater than the percentage content by weight of Chromium in the second thermal bond coating 12. Therefore, a Sulphur adsorption coefficient of the first thermal bond coating 11 is greater than a Sulphur adsorption coefficient of the second thermal bond coating 12, because of greater availability of Chromium in the first thermal bond coating 11 as compared with the second thermal bond coating 12. Protection of the inner core 6 of the airfoil 1 may be enhanced even if the second thermal bond coating 12 experiences depletion due to the aforementioned sulphur attacks.

Herein, “the Sulphur adsorption coefficient” is to be construed as the ratio of mass of Sulphur adsorbed per unit mass of the thermal bond coating material.

Due to oxidation of the outer surface 14 of the second thermal bond coating 12 during the operation of the airfoil 1, a thermally grown oxide may be formed between the second thermal bond coating 12 and the outer ceramic coating 8. The thermally grown oxide may hamper the bonding between the second thermal bond coating 12 and the outer ceramic coating 8. According to an exemplary aspect of the present invention, the rate of growth of the thermally grown oxide can be reduced due to a higher percentage content by weight of Aluminium in the second thermal bond coating 12 as compared with the first thermal bond coating 11. The higher percentage content of Aluminium in the second thermal bond coating 12 facilitates the formation of the Alfa-Alumina, which is thermodynamically stable, and reduces the rate of growth of the thermally grown oxide.

In accordance with one or more embodiments of the present invention, the first thermal bond coating 11 and the second thermal bond coating 12 are optimized to operate up to a first maximum temperature T₁ₘₐₓ and a second maximum temperature T₂ₘₐₓ respectively. Since the second thermal bond coating 12 is arranged underneath the outer ceramic coating 8, and since the first thermal bond coating 11 is arranged underneath the second thermal bond coating 12, the second thermal bond coating 12 experiences higher thermal stresses as compared to the first thermal bond coating 11 during the operation of the airfoil 1, because of the proximity of the second thermal bond coating 12 to the hot gases 5. Furthermore, the latency of heat transfer from the outer ceramic coating 8 to the second thermal bond coating 11 is lesser compared to the latency of heat transfer from the second thermal bond coating 12 to the first thermal bond coating 11. Considering the aforementioned factors, the second maximum temperature T₂ₘₐₓ is preferably higher than the first maximum temperature T₁ₘₐₓ. Thus, the second thermal bond coating 12 is capable of withstanding higher temperatures than the first thermal bond coating 11.

The second thermal bond coating 12 is capable of operating at temperatures far greater than 1173 k, and the first thermal bond coating 11 comprising SC 2231 is capable of operating at temperatures less than 1173 k.

In order to optimize the cost of the thermal bond coating layer 7, in accordance with one or more other embodiments of the present invention, a thickness t₁ of a first thermal bond coating 11 is greater than a thickness t₂ of the second thermal bond coating 12. The thickness t₁ of the first thermal bond coating 11 lies in the range of 100 μm to 300 μm, whereas the thickness t₂ of the second thermal bond coating 12 lies in the range of 10 μm to 100 μm. Preferably, a 200 μm thick first thermal bond coating 11 and a 10 to 100 μm thick second thermal bond coating 12 is an optimal configuration of the thermal bond coating layer 7 for the airfoil 1. In addition to the aforementioned advantage, the inner core 6 of the airfoil 1 is protectable to a greater extent if the thickness t of the first thermal bond coating 11 is greater than the thickness t₂ of second thermal bond coating 12, because the first thermal bond coating 11 will be capable of adsorbing more Sulphur compared to the second thermal bond coating 12, and therewith the depletion of the first thermal bond coating 12 is reduced. Therewith the operational life of the airfoil 1 is extended.

Furthermore, it may be noted herein that the second thermal bond coating 12 is arranged as a coarse layer on the first thermal bond coating 11. The coarseness of the second thermal bond coating 12 facilitates the achievement of enhanced bonding with the outer ceramic coating 8, thereby enhancing the rigidity of the airfoil 1.

In the event of a development of a crack in the outer ceramic coating 8, which may be experienced during the operation of the airfoil, the second thermal bond coating 12 is exposed to the working fluid, and the fuel used in the turbomachine. The fuel, the working fluid, and the contaminants thereof can cause oxidation and spallation of the second thermal bond coating 12, thereby leading to the depletion of the second thermal bond coating 12. This phenomenon can subsequently expose the first thermal bond coating 11 and thereafter the inr core 6, thereby leading to a progressive degradation of the airfoil 1. In order to prevent the depletion and the resulting degradation of the second thermal bond coating 12, according to another embodiment of the present invention, the second thermal bond coating 12 comprises Rhenium. Rhenium facilitates the operation of the second thermal bond coating 12 to very high operational temperatures, for example up to 2500° C. I.e., it is possible to enhance the second maximum temperature T₂ₘₐₓ. Additionally, Rhenium is also resistant to water Vapor, which is advantageous in the prevention of oxidation and corrosion of the second thermal bond coating 12. Furthermore, the excellent wear resistance of Rhenium renders strength and durability to the second thermal bond coating.

A flowchart 100 of a method for construction of airfoil 1 in accordance with one or more embodiments of the present invention is depicted in FIG. 4.

In step 110, the inner core of the airfoil 1 is provided. In step 120, the first thermal bond coating 11 is provided on the portion 10 of the inner core 6. The first thermal bond coating 11 can be provided by overlaying the first thermal bond coating 11 on the outer surface 9 of the inner core 6 by any of the aforementioned processes. In step 130, the second thermal bond coating 12 is provided on the first thermal bond coating 11. The second thermal bond coating 12 can be provided by overlaying the second thermal bond coating 12 on the outer surface 13 of the first thermal bond coating II by means of any of the aforementioned processes. Thereafter, in step 140, the outer ceramic coating 8 is provided on the second thermal bond coating 12. The outer ceramic coating 8 can be provided by overlaying the outer ceramic coating 8 on the outer surface 14 of the second thermal bond coating 12 in accordance with any of the aforementioned well-known processes.

The teachings of the present invention can also be used for construction of a cost-effective and highly durable platform segment 2. The platform segment 2 may comprise an inner core (not shown) with an outer surface 15, a first thermal bond coating can be overlaid. Preferably, the outer surface 15 is the radial outer surface of the platform segment 2 as depicted in FIG. 1. Subsequently, a second thermal bond coating can be overlaid on the first thermal bond coating. An outer ceramic coating can be overlaid on the second thermal bond coating, thereby facilitating obtaining of the platform segment.

Though the invention has been described herein with reference to specific embodiments, this description is not meant to be construed in a limiting sense. Various examples of the disclosed embodiments, as well as alternate embodiments of the invention, will become apparent to persons skilled in the art upon reference to the description of the invention. It is therefore contemplated that such modifications can be made without departing from the embodiments of the present invention as defined.

1. A component for a turbomachine, the component comprising:
an inner core having an outer surface;
a first thermal bond coating disposed on the outer surface on at least a portion of the inner core, the first thermal bond coating is optimized to operate up to a first maximum temperature (T₁ₘₐₓ);
a second thermal bond coating disposed on the first thermal bond coating, such that the first thermal bond coating is located between the second thermal bond coating and the outer surface of the inner core, the second thermal bond coating is optimized to operate up to a second maximum temperature (T₂ₘₐₓ);
wherein the second maximum temperature (T₂ₘₐₓ) is greater than the first maximum temperature (T₁ₘₐₓ);
wherein a thickness (t₁) of the first thermal bond coating is greater than a thickness (t₂) of the second thermal bond coating; and
wherein a percentage by weight of Chromium of which the first thermal bond coating is comprised
is greater than a percentage by weight of Chromium of which the second thermal bond coating is comprised.

2. The component according to claim 1, wherein the thickness (t₂) of the second thermal bond coating is in the range of 10 μm to 100 μm.

3. The component according to claim 2, wherein the thickness (t₁) of the first thermal bond coating is in the range of 100 μm to 300 μm.

4. The component according to claim 1, wherein the first thermal bond coating is configured and capable of adsorbing Sulphur.

5. The component according to claim 4, wherein the second thermal bond coating is configured and capable of adsorbing Sulphur and wherein a Sulphur adsorption coefficient of the first thermal bond coating is greater than a Sulphur adsorption coefficient of the second thermal bond coating.

6. The component according to claim 1, wherein the second thermal bond coating comprises Rhenium.

7. The component according to claim 1, wherein the first maximum temperature (T₁ₘₐₓ) is less than or equal to 900° C.

8. The component according to claim 7, wherein the second maximum temperature (T₂ₘₐₓ) is greater than 900° C.

9. (canceled)

10. The component according to claim 1, further comprising:
an outer ceramic coating disposed on the second thermal bond coating, such that the first thermal bond coating and the second thermal bond coating are sandwiched between the outer surface of the inner core and the outer ceramic coating.

11. The component according to, claim 1 wherein the second thermal bond coating comprises by weight:
Cobalt—24 to 26%, Chromium—16 to 18%, Aluminium—9.5 to 11%, Yttrium—0.2 to 0.4%, Rhenium—1.2 to 1.8%, and a remainder comprises Nickel, and/or the first bond coating comprises by weight: Nickel—29 to 31%, Chromium—27 to 29%, Aluminium—7 to 8%, Yttrium—0.5 to 0.7%, Silicon—0.3 to 0.7% Si, and a remainder comprises Cobalt.

12. A method for construction of a component for a turbomachine, wherein the component is comprised according to claim 1, the method comprising steps of:
providing the first thermal bond coating on the outer surface on the portion of the inner core; and
providing the second thermal bond coating on the first metallic thermal bond coating.

13. The method according to claim 12, wherein the step of providing the first thermal bond coating comprises overlaying the first thermal bond coating on the outer surface on the portion of the inner core.

14. The method according to claim 12, wherein the step of providing the second thermal bond coating comprises overlaying the second thermal bond coating on the first thermal bond coating.

15. The method according to claim 12, further comprising providing at least one of the first thermal bond coating and the second thermal bond coating by a process selected from the group consisting of Electron Beam Physical Vapor Deposition, Air Plasma Spray, High Velocity Oxygen Fuel, Electrostatic Spray Assisted Vapour Deposition, and Direct Vapour Deposition.

16. The method according to claim 13, wherein the step of providing the second thermal bond coating comprises overlaying the second thermal bond coating on the first thermal bond coating.

17. The component according to claim 1, wherein the thickness (t₁) of the first thermal bond coating is in the range of 100 μm to 300 μm.

18. The component according to claim 1, wherein the second maximum temperature (T₂ₘₐₓ) is greater than 900° C.
